(19) United States
(12) Patent Application Publication
(10) Pub. No.: US 2015/0107088 A1
(43) Pub. Date: Apr. 23, 2015

(54) COMPONENT MOUNTING SYSTEM AND COMPONENT MOUNTING METHOD

(71) Applicant: Panasonic Intellectual Property Management Co., Ltd., Osaka (JP)

(72) Inventors: Hiroki SAGARA, Yamanashi (JP); Takuya YAMAZAKI, Yamanashi (JP); Hirokazu TAKEHARA, Yamanashi (JP)

(21) Appl. No.: 14/520,953

(22) Filed: Oct. 22, 2014

(30) Foreign Application Priority Data
Oct. 23, 2013 (JP) 2013-219763

(51) Int. Cl. H05K 13/04; G06Q 10/06; G05B 15/02

(52) U.S. Cl. CPC H05K 13/0495; G05B 15/02; G06Q 10/063114
USPC 29/592.1; 29/742

(57) ABSTRACT

A component mounting system includes a component mounting line including series-connected component mounting machines. In the component mounting system, workers execute jobs for equipment operation of the component mounting line. The component mounting system includes: a skill level storage unit which stores worker data in which a worker ID for identifying each of the workers is associated with a skill level of the corresponding worker for execution of each of the jobs; a history data storage unit which stores execution results of the jobs executed by the workers as job history data for each of the workers; and a worker data update unit which updates the skill level of each of the workers in the worker data based on a result of determination extracted from the job history data.

### BACKGROUND

1. Technical Field

One or more aspects of the present invention relates to a component mounting system and a component mounting method for mounting electronic components on a substrate.

2. Background Art

In a component mounting system for manufacturing a mounted board for use in an electronic apparatus, component mounting work for mounting electronic components in a component mounting line where component mounting machines are connected is executed repeatedly. In the component mounting work, workers in charge of equipment operation are requested to execute various jobs, including routine jobs about supply of components, teaching of component recognition, etc., and further, individually corresponding jobs for dealing with occurrence of machine troubles, etc. The technique level required for correctly executing those jobs differs from one job type to another. To execute a job for which a high skill level is required, workers to whom the job can be assigned are limited.

For the sake of such suitable assignment to workers, in the related art, worker data indicating the skill level of each worker in advance are created for the worker in advance, so that, with reference to the worker data, each job can be assigned to a worker whose skill level corresponds to the skill level required for the job (for example, see JP-A-9-326599). In the related art such as JP-A-9-326599, a personnel master file is prepared. In the personnel master file, a skill level indicating the job skill of each maintenance personnel engaging in related jobs is associated with the name and the employee code of the personnel.

### SUMMARY

In the worker data created for identifying the skill level in the related art such as JP-A-9-326599, however, a problem arises due to the data contents set fixedly, as will be described below. That is, the skill level of each worker has a characteristic which is improved in accordance with the job learning degree of the worker, but the job learning degree is not always reflected in the worker data. The contents of the worker data are not always suitable as data to be referred to for suitable assignment of jobs. In addition, it is not practical but troublesome for a maintainer to determine the skill level of each worker and reflect the skill level in the worker data to update the worker data. It has been therefore desired to update the worker data suitably.

An object of one or more aspects of the present invention is to provide a component mounting system and a component mounting method capable of automatically updating contents of worker data indicating the skill level of each worker so as to keep the contents suitable.

In one aspect of the present invention, there is provided a component mounting system which comprises a component mounting line including series-connected component mounting machines and in which workers execute jobs for equipment operation of the component mounting line, the component mounting system including: a skill level storage unit which stores worker data in which a worker ID for identifying each of the workers is associated with a skill level of the corresponding worker for execution of each of the jobs; a history data storage unit which stores execution results of the jobs executed by the workers as job history data for each of the workers; and a worker data update unit which updates the skill level of each of the workers in the worker data based on a result of determination extracted from the job history data.

In another aspect of the present invention, there is provided a component mounting method in which workers execute jobs for equipment operation of a component mounting line including series-connected component mounting machines, the component mounting method including: storing worker data in which a worker ID for identifying each of the workers is associated with a skill level of the corresponding worker for execution of each of the jobs; storing results of execution of the jobs executed by the workers as job history data for each of the workers; and updating the skill level of each of the workers in the worker data based on a result of determination extracted from the job history data.

According to one or more aspects of the present invention, in component mounting in which jobs in equipment operation for operating a component mounting line are executed by workers, worker data in which a worker ID for identifying each worker is associated with the skill level with which the worker can execute each job is stored while an execution result of each job executed by each worker is stored as job history data of the worker in advance, and the skill level of each worker in the worker data is updated based on a determination result extracted from the job history data so that the contents of the worker data indicating the skill level of each worker can be updated automatically and kept suitable.

### BRIEF DESCRIPTION OF THE DRAWINGS

FIG. 1 is a diagram for explaining the configuration of a component mounting system according to an embodiment of the invention;

FIG. 2 is a plan view of a component mounting machine for use in the component mounting system according to the embodiment of the invention;

FIG. 3 is a partial sectional view of the component mounting machine for use in the component mounting system according to the embodiment of the invention;

FIG. 4 is a block diagram showing the configuration of a control system in the component mounting system according to the embodiment of the invention;

FIG. 5 is a diagram for explaining worker data in the component mounting system according to the embodiment of the invention;

FIG. 6 is a diagram for explaining an input screen of a terminal device operated by a worker in the component mounting system according to the embodiment of the invention; and

FIG. 7 is a flow chart showing a worker data updating process in a component mounting method according to the embodiment of the invention.

### DETAILED DESCRIPTION

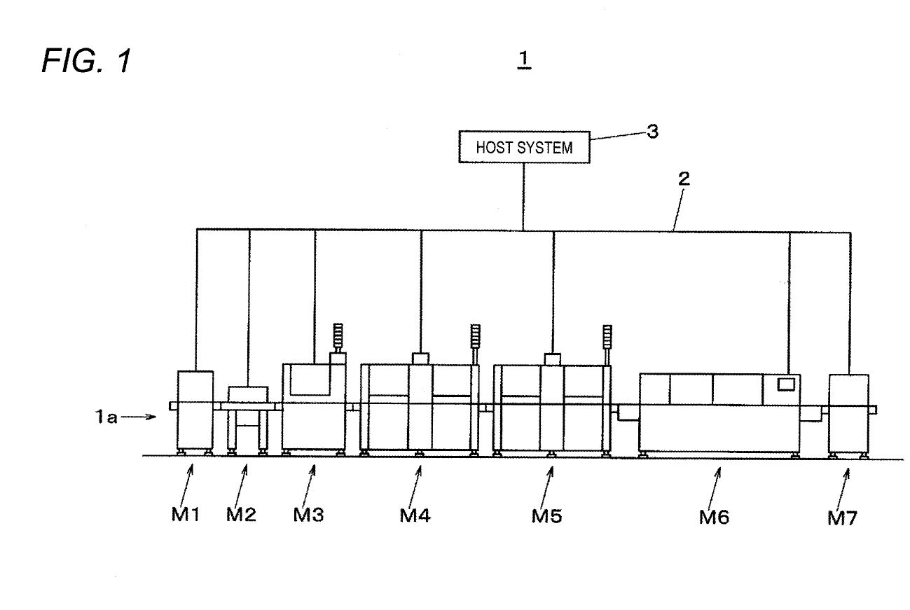

Next, an embodiment of the invention will be described with reference to the drawings. First, the configuration of a component mounting system 1 will be described with reference to FIG. 1. The component mounting system 1 has a function of mounting electronic components on a substrate to produce a mounted board. The component mounting system 1 is mainly constituted by a component mounting line 1a. The component mounting line 1a has a configuration in which a plurality of electronic component mounting machines including a solder printing unit M3, component mounting units M4 and M5 and a reflow unit M6 are connected in series among a substrate supply machine M1, a substrate delivery machine M2 and a substrate recovery machine M7 which have functions of supplying, delivering and recovering the substrate to be mounted with the electronic components, respectively. Each of the substrate supply machine M1 to the substrate recovery machine M7 is connected to a host system 3 through a communication network 2. The host system 3 has a management computer.

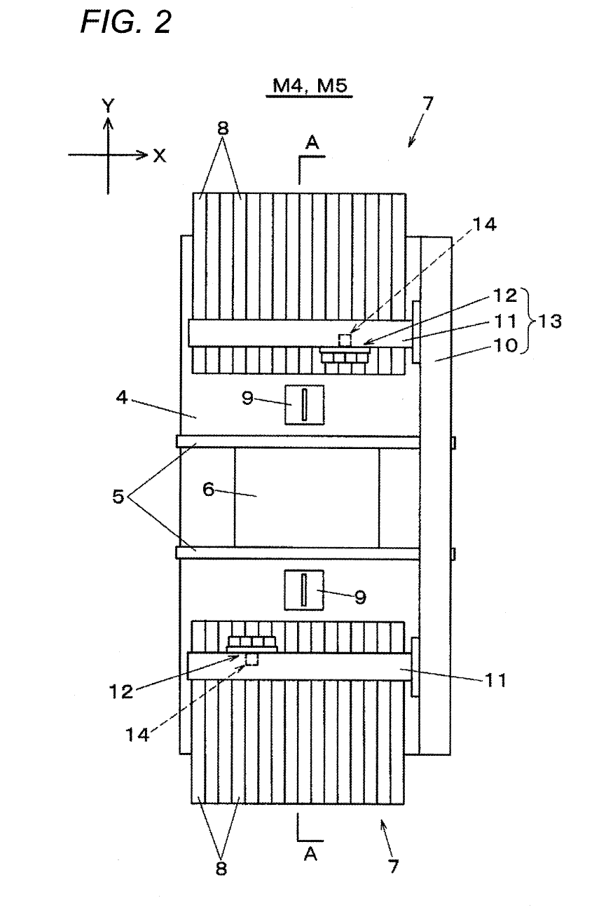

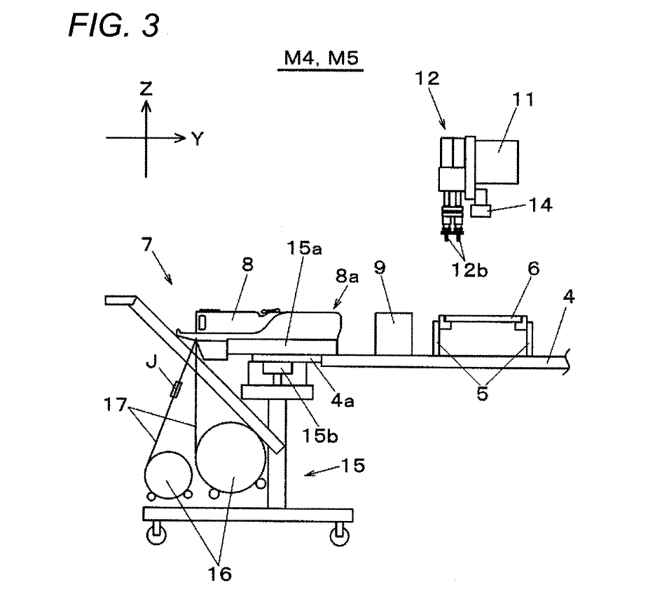

In the component mounting work, component mounting jobs for mounting electronic components on a substrate 6 conveyed along the component mounting line 1a (see FIGS. 2 and 3) is carried out by the solder printing machine M3, the component mounting machines M4 and M5 and the reflow machine M6. That is, the substrate 6 supplied by the substrate supply machine M1 is conveyed to the solder printing machine M3 through the substrate delivery machine M2, and a solder printing job in which solder for joining components is screen-printed on the substrate 6 is carried out in the solder printing machine M3.

The substrate 6 printed with solder is delivered to the component mounting machines M4 and M5 sequentially, and a component mounting job for mounting electronic components on the substrate 6 printed with solder is carried out in the component mounting machines M4 and M5. The substrate 6 mounted with the components is then conveyed to the reflow machine M6, and heated in the reflow machine M6 in accordance with a predetermined heating profile so that the solder for joining the components can be melted and solidified. Thus, a mounted board in which the electronic components have been soldered and joined to the substrate 6 and the electronic components have been mounted on the substrate 6 is completed, and recovered by the substrate recovery machine M7.

Next, the structure of each component mounting machine M4, M5 will be described with reference to FIGS. 2 and 3. Incidentally, FIG. 3 shows a section taken on line A-A in FIG. 2. In FIG. 2, a substrate conveyance mechanism 5 is disposed in an X direction on a base 4. The substrate conveyance mechanism 5 conveys the substrate 6 to be mounted with electronic components, by means of a conveyor, and positions the substrate 6 in a mounting job position which is set on the substrate conveyance mechanism 5. Component supply units 7 are provided on opposite sides of the substrate conveyance mechanism 5, and a plurality of tape feeders 8 serving as component supply machines are provided in parallel in each component supply unit 7. Each tape feeder 8 pitch-feeds a carrier tape holding electronic components to be mounted, so as to supply each electronic component to a component suction position where the component will be sucked by a suction nozzle 12a of a mounting head 12 as will be described below.

A Y-axis moving table 10 provided with a linear drive mechanism is disposed in one end portion in the X-direction in the upper surface of the base 4. Two X-axis moving tables 11 each provided with a linear drive mechanism in the same manner as the Y-axis moving table 10 are coupled movably in a Y direction on the Y-axis moving table 10. Mounting heads 12 are mounted movably in the X direction on the two X-axis moving tables 11 respectively. Each mounting head 12 is a multiple type head provided with a plurality of holding heads. Suction nozzles 12a which can suck and hold electronic components and move up/down individually are attached to the lower end portions of the holding heads respectively as shown in FIG. 3.

When the Y-axis moving table 10 and the X-axis moving tables 11 are driven, the mounting heads 12 can move in the X direction and the Y direction. Thus, the two mounting heads 12 extract electronic components from the component suction positions of the tape feeders 8 of their corresponding component supply units 7 by means of the suction nozzles 12a respectively, and transport and mount the extracted electronic components onto mounting points on the substrate 6 positioned by the substrate conveyance mechanism 5. The Y-axis moving table 10, the X-axis moving tables 11 and the mounting heads 12 constitute a component mounting mechanism 13 for moving the mounting heads 12 to transport and mount electronic components onto the substrate 6.

A component recognition camera 9 is disposed between each component supply unit 7 and the substrate conveyance mechanism 5. When the corresponding mounting head 12 extracting an electronic component from the component supply unit 7 is moving above the component recognition camera 9, the component recognition camera 9 takes an image of the electronic component held by the mounting head 12 and recognizes the electronic component. A substrate recognition camera 14 is attached to each mounting head 12 so as to be located on the lower surface side of the corresponding X-axis moving table 11 and move integrally with the mounting head 12. When the mounting head 12 moves, the substrate recognition camera 14 moves above the substrate 6 positioned by the substrate conveyance mechanism 5, takes an image of the substrate 6, and recognizes the substrate 6. In the operation of mounting an electronic component on the substrate 6 by means of the mounting head 12, the position where the component should be mounted is corrected in consideration of both the recognition result of the electronic component by the component recognition camera 9 and the recognition result of the substrate by the substrate recognition camera 14.

As shown in FIG. 3, a carriage 15 in which a plurality of tape feeders 8 have been attached to a feeder base 15a is set in each component supply unit 7. The feeder base 15a is clamped onto a fixed base 4a, which is provided in the base 4, by a clamp mechanism 15b so as to fix the position of the carriage 15 in the component supply unit 7. Supply reels 16 which receive the carrier tapes 17 holding electronic components and wound respectively are held on the carriage 15. The carrier tapes 17 extracted from the supply reels 16 are pitch-fed to pick-up positions 8a, where the electronic components will be picked up by the suction nozzle 12a, by the tape feeders 8.

Each component mounting machine M4, M5 illustrated in the embodiment uses a tape splicing system in which a tail portion of a carrier tape 17 (preceding tape), which has been attached to a tape feeder 8, can be spliced to a head portion of a carrier tape 17 (succeeding tape), which will be attached newly when components are depleted, through a splice portion J using a joining tape. Thus, the carrier tapes 17 can be continuously supplied to the tape feeders 8 without interrupting due to replacement of the supply reels 16.

Then the mounting head 12 gains access to the pick-up position 8a of each tape feeder 8 and carries out a component suction operation, so that an electronic component is extracted from the pick-up position 8a by the suction nozzle 12a. Next the mounting head 12 which has extracted the electronic component moves above the corresponding component recognition camera 9. An image of the electronic component held by the mounting head 12 is taken by the component recognition camera 9. Thus, the component can be recognized.

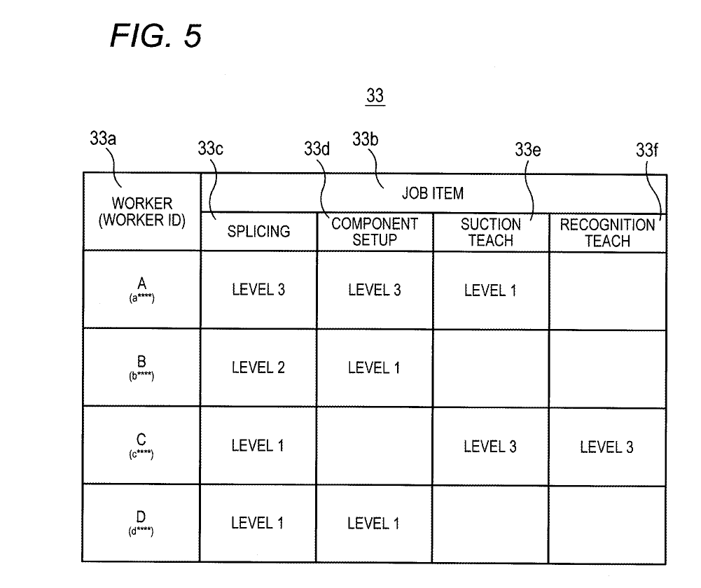

In the process of executing the aforementioned component mounting operation, various jobs including a component setup job for mounting the supply reels 16 on the carriage 15, a splicing job for splicing a preceding tape, which has been attached, to a new succeeding tape, a suction teaching job for checking operation conditions at the time of sucking and extracting an electronic component by the mounting head 12 and making adjustment in accordance with necessity, a recognition teaching job for checking recognition conditions as a result of imaging by the component recognition camera 9 and making adjustment in accordance with necessity, etc. (see splicing 33c, component setup 33d, suction teach 33e and recognition teach 33f shown in FIG. 5) are carried out by workers in charge.

These jobs differ in difficulty from one job to another. The workers carrying out the jobs are requested to have skill required for job items respectively. Therefore, in the component mounting system 1 according to the embodiment, worker data are stored in advance for workers who may be in charge of those job items. In the worker data, a worker ID for identifying each worker is associated with the skill level with which the worker can execute each of the aforementioned jobs. When jobs are assigned to the workers, each job is assigned to each worker in accordance with the skill level of the worker with reference to the worker data. That is, the component mounting system 1 according to the embodiment has a configuration in which a component mounting line 1a having a plurality of component mounting machines M4 and M5 connected with each other is provided, and jobs for equipment operation of the component mounting line 1a are executed by a plurality of workers.

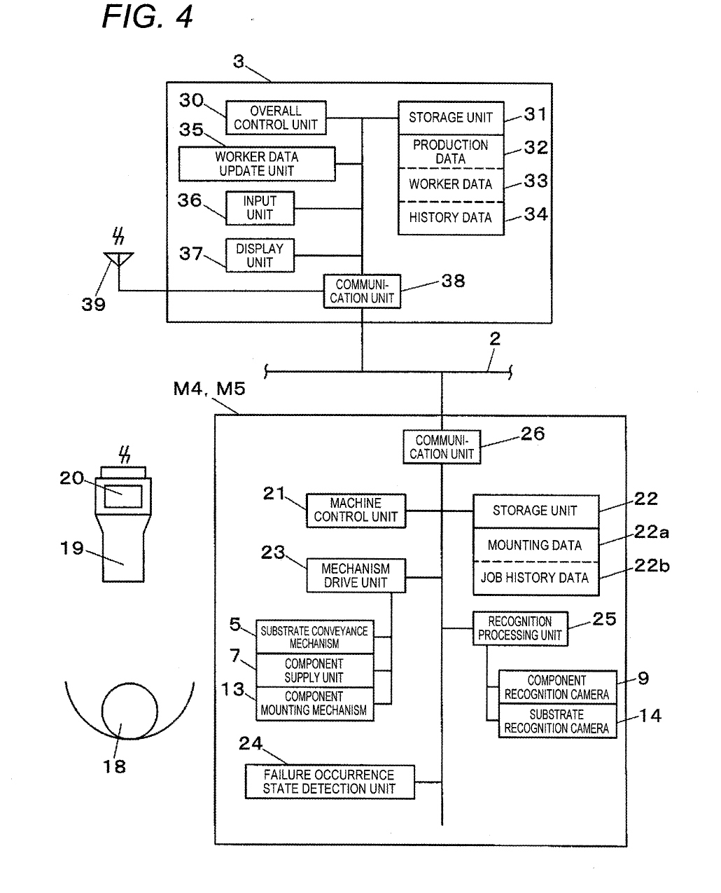

Next the configuration of the control system will be described with reference to FIG. 4. In FIG. 4, each component mounting machine M4, M5 has a machine control unit 21, a storage unit 22, a mechanism drive unit 23, a failure occurrence state detection unit 24 and a recognition processing unit 25. The machine control unit 21 is a processing calculation unit, which executes various programs stored in the storage unit 31, so as to control each unit which will be described below, and to thereby make the component mounting machine M4, MS execute job operations or various kinds of processing. In addition to mounting operation programs, mounting data 22a, etc. required for the component mounting work, job history data 22b in which execution results of jobs carried out by each worker are collected as a job history are stored in the storage unit 22.

The mechanism drive unit 23 is controlled by the machine control unit 21 so as to drive the substrate conveyance mechanisms 5, the component supply unit 7 and the component mounting mechanisms 13. The machine control unit 21 controls the aforementioned mechanism units with reference to the mounting data 22a stored in the storage unit 22, so that the component mounting work can be executed. The recognition processing unit 25 performs recognition processing on results of imaging by the component recognition cameras 9 and the substrate recognition cameras 14. A communication unit 26 is a communication interface, which exchanges signals with another device or the host system 3 through the communication network 2.

A sensor for checking operation, a sensor for monitoring condition, etc. are provided at some places of each mechanism unit in the component mounting machines M4 and M5. When some abnormality occurs during equipment operation, these sensors generate signals corresponding to the condition. Each sensor for checking operation generates a predetermined signal at a predetermined normal timing or at a predetermined normal sequence when a mechanism corresponding to the sensor operates normally. Once abnormal operation occurs, a signal indicating a sign of abnormality is generated. For example, such a signal is missed or disordered as to its generation timing.

As for misregistration of a tape feeder 8 in each component supply unit 7, falling of foreign matter into a mechanism, clogging of a suction nozzle 12a or a valve, etc., dedicated sensors provided for such abnormalities respectively send signals indicating the presence/absence of abnormality. Further, the recognition processing unit 25 executes a recognition process in accordance with a predetermined algorithm. Due to a failure of an acquired image or the like, there may be a case that a correct recognition result cannot be obtained. In this case, a recognition error is determined and a signal indicating the recognition error is sent. The failure occurrence state detection unit 24 detects a failure occurrence state in job execution of each unit in the component mounting machines M4 and M5 based on detection signals from the aforementioned sensors for checking operation and for monitoring condition, the recognition result acquired from the recognition processing unit 25, etc. Data of the detected failure occurrence state are stored into the storage unit 22 in times series as job history data 22b.

When each worker 18 performs operation, maintenance or the like on the substrate conveyance mechanism 5, the component supply unit 7 or the component mounting mechanism 13 for the sake of job execution for operating the component mounting machine M4 or M5, the worker 18 inputs a predetermined item through an input screen 20 provided in a terminal device 19 for operation. Consequently a job history for each worker in each component mounting machine M4, M5 is transmitted to the host system 3.

The host system 3 has an overall control unit 30, a storage unit 31, a worker data update unit 35, an input unit 36, a display unit 37 and a communication unit 38. The overall control unit 30 is a processing calculation unit, which controls the following unit based on programs and data stored in the storage unit 31 so as to manage the whole of the component mounting system 1. The storage unit 31 stores production data 32, worker data 33 and history data 34.

The production data 32 are data which should be referred to when jobs for mounting components are carried out by the respective machines constituting the component mounting system 1. The worker data 33 are data in which a worker ID for identifying each worker is associated with the skill level with which the worker can execute each job. That is, as shown in FIG. 5, the worker data 33 have a data configuration in which a skill level for each job (the splicing 33c, the component setup 33d, the suction teach 33e and the recognition teach 33f here) shown in a job item field 33b is defined for each of a plurality of workers (A, B, C and D) shown in a worker field 33a.

A unique worker ID (a****, b****, c****, d****) is given to each worker (A, B, C, D). Workers input their own worker IDs for job execution so that the workers engaging in the job execution can be identified on job history data which will be described below. In addition, the skill level is set in three stages from Level 1 to Level 3, which indicates that a worker with a larger level number has a higher degree of skill and can execute a more difficult job.

The history data 34 stores execution results of jobs executed by the workers as job history data for each of the workers. The job history data are created based on the job history data 22b stored in the component mounting machines M4 and M5 and transmitted through the communication network 2 and data transmitted through the terminal device 19 by each worker 18. The created job history data include information indicating a change in failure occurrence state of equipment operation before and after each job.

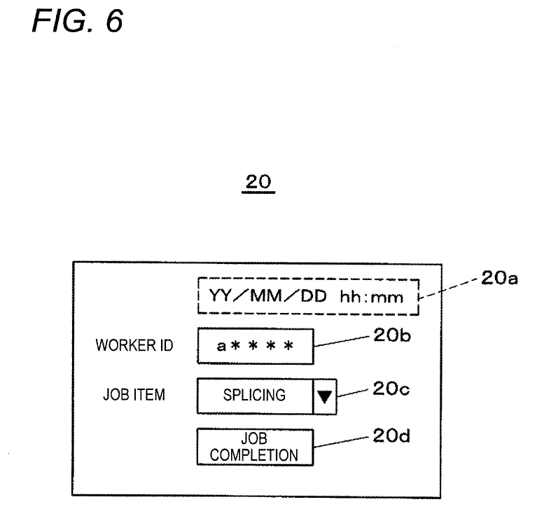

FIG. 6 shows an input screen displayed on the input screen 20 of the terminal device 19 operated by each worker 18. A date and hour frame 20a indicating the date and hour at the time of the operation are displayed on the input screen 20, and the hour at that time is associated with data at the time inputted for the following items. The worker 18 executing a job inputs his/her own worker ID into a worker input frame 20b. A job selection frame 20c is an input frame in which the worker selects and designates a job item the worker wants to execute at the time of the operation. Each job shown in the job item field 33b in FIG. 5 can be designed by touch input. When touch input is performed on a job completion input frame 20d, the fact that the job has been completed is inputted and transmitted to the host system 3.

In the aforementioned configuration, the storage unit 31 serves as a skill level storage unit for storing worker data in which a worker ID for identifying each worker is associated with the skill level with which the worker can execute each job, and also serves as a history data storage unit for storing job history data for each worker, which data indicate execution results of jobs executed by the worker.

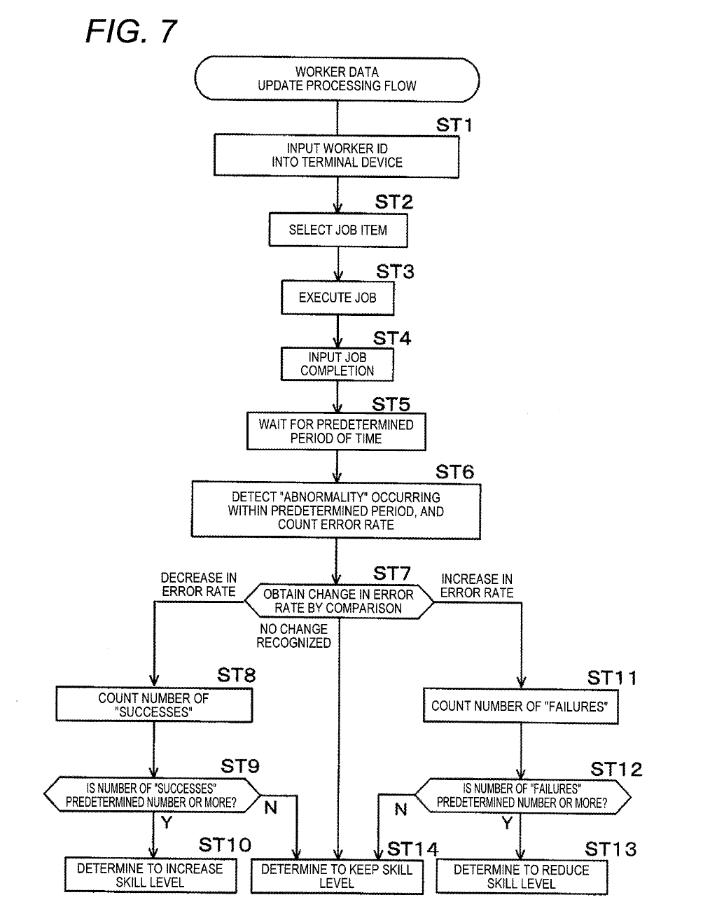

The worker data update unit 35 performs processing for updating the skill level of each worker in the worker data 33 based on a determination result extracted from the job history data stored in the history data 34. Here, the determination result is derived from a change in error rate indicating a change in failure occurrence state of equipment operation before and after the execution of each job (see the flow shown in FIG. 7).

The input unit 36 is an input device such as a keyboard or a touch panel built in the display unit 37. The input unit 36 performs operation for inputting an operation command or data. The display unit 37 is a display device such as a liquid crystal panel. The display unit 37 displays a guide screen for making an input through the input unit 36, the worker data 33 shown in FIG. 5, etc. The communication unit 38 is a communication interface, which exchanges signals with each machine constituting the component mounting system 1 or receives data wirelessly transmitted from the terminal device 19 through a radio device 39.

Next, description will be made about a component mounting method carried out by the component mounting system 1. This component mounting method has a work form in which jobs for equipment operation of the component mounting line 1a are executed by a plurality of workers. According to the embodiment, in order to reasonably assign the jobs to a plurality of workers with different skill levels, the worker data 33 in which a worker ID for identifying each worker is associated with the skill level with which the worker can execute each job is stored in advance (skill level storing step).

The worker data 33 configured thus are data which are characterized by changing in accordance with the job learning degree of each worker. In the embodiment, therefore, the worker data 33 are maintained and updated based on real data acquired in the process of executing component mounting work. That is, an execution result of each job executed by each worker is stored as job history data of the worker (history data storing step), and the skill level of each worker in the worker data 33 is updated by the processing function of the worker data update unit 35 based on a determination result extracted from the stored job history data (worker data update step).

With reference to FIG. 7, description will be made about the details of the aforementioned process for updating the worker data. First, when a worker 18 is to execute a job, the worker 18 inputs his/her own worker ID into the worker input frame 20b on the input screen 20 of the terminal device 19 (see FIG. 6) (ST1). Next, the worker 18 selects a job item (ST2), and executes the selected job item (ST3). That is, of the job item field 33b shown in FIG. 5, a job to be executed is selected in the job selection frame 20c, and the selected job is then executed. Here, a case where the splicing 33c is selected as a job to be executed will be described by way of example.

For the splicing 33c, a job for splicing a preceding tape, which has been attached to a tape feeder 8, to a new succeeding tape through a joining tape is carried out. When the job is terminated to finish splicing the preceding tape to the succeeding tape, the worker 18 inputs job completion into the job completion input frame 20d (ST4). A wait for a predetermined period of time is performed after the job completion (ST5). Here the predetermined period corresponds to a period until a certain time has passed since the splice portion J (see FIG. 3) between the preceding tape and the succeeding tape passed through the pickup position 8a of the tape feeder 8 and the succeeding tape entered the pickup position 8a entirely. The predetermined period is set for empirical confirmation about whether the execution of the job gave rise to some abnormality on the equipment operation or not.

That is, “abnormality” occurring within the predetermined period is detected, and an error rate is counted. Here, “abnormality” set in advance as phenomena related to splicing, such as a suction error when a component is sucked by the suction nozzle 12a, a tape feeding error in the tape feeder 8, etc., is the target of the error rate as an index of the failure occurrence state of equipment operation. The counted error rate is compared with a preceding error rate stored in the history data 34, that is, an error rate before the execution of the job, and a change in error rate before and after the execution of the job is obtained by the comparison (ST7).

Here, when it is determined that the error rate decreases, the following process is performed. That is, it is determined whether the detected decreasing quantity of the error rate exceeds a threshold regarded as “success” on job quality evaluation of the job or not, and the number of successes is counted when the job is regarded as “success” (ST8). The threshold is set suitably based on experience values or trial results. It is then determined whether a predetermined number or more “successes” are recognized within a predetermined evaluation target period or not (ST9). Here, when the predetermined number or more “successes” are recognized, it is determined that the skill about the job has been improved, and it is determined to increase the skill level (ST10). Thus, the skill level of the worker in the worker data 33 is ranked up from the current level.

On the contrary, when it is determined in (ST7) that the error rate increases, the following process is performed. That is, it is determined whether the detected increasing quantity of the error rate exceeds a threshold regarded as “failure” on job quality evaluation of the job or not, and the number of failures is counted when the job is regarded as “failure” (ST11). The threshold is set suitably based on experience values or trial results. It is then determined whether a predetermined number or more “failures” are recognized within a predetermined evaluation target period or not (ST12). Here, when the predetermined number or more “failures” are recognized, it is determined that the skill has deteriorated, and it is determined to reduce the skill level (ST13). Thus, the skill level of the worker in the worker data 33 is ranked down from the current level.

Incidentally, when no change in error rate is recognized in (ST7), when the predetermined number or more “successes” are not recognized in (ST9), or when the predetermined number or more “failures” are not recognized in (ST12), it is determined to keep the skill level (ST14), but the skill level in the worker data 33 is not updated.

When the contents of the worker data 33 are updated automatically thus, the updated worker data 33 can be always referred to for assignment of jobs to workers in the component mounting system 1 with reference to. Accordingly, the jobs can be assigned optimally in accordance with the skill level of each worker. Further, when the skill level of each worker in the worker data 33 is evaluated, it can be determined what technical training is required. Accordingly, the worker data 33 becomes a useful resource for improving the skill level in the production site as a whole.

Although “success” is determined in accordance with whether the decreasing quantity of the error rate exceeds the predetermined threshold or not in the aforementioned embodiment, “success” may be determined in consideration of the work time spent for the target job together with the decreasing quantity of the error rate. In this case, “success” is determined only when the decreasing quantity of the error rate exceeds the predetermined threshold and the work time spent for the job is within a predetermined time set as standard target time in advance. Specifically the worker executes “job start input” before the job execution (ST3), and the work time for the job is calculated after the “job completion input” (ST4). It is determined whether the calculated work time is within a predetermined time or not, and the result of the determination is combined with the determination based on the decreasing quantity of the error rate to determine whether to regard the job as “success” or not.

As has been described above, in the component mounting method using the component mounting system 1 according to the embodiment, in component mounting in which jobs for equipment operation of the component mounting line 1a are executed by workers, the worker data 33 in which a worker ID for identifying each worker is associated with the skill level with which the worker can execute each job are stored while an execution result of each job executed by each worker is stored as the history data 34 including job history data of the worker in advance, and the skill level of each worker in the worker data 33 is updated based on a determination result extracted from the job history data. Thus, the contents of the worker data 33 indicating the skill level of each worker can be updated automatically and kept suitable.

A component mounting system and a component mounting method according to one or more aspects of the present invention have an effect that the contents of worker data indicating the skill level of each worker can be updated automatically and kept suitable. The component mounting system and the component mounting method are useful in the field in which electronic components are mounted on a substrate to manufacture a mounted board.

What is claimed is:

1. A component mounting system which comprises a component mounting line comprising series-connected component mounting machines and in which workers execute jobs for equipment operation of the component mounting line, said component mounting system comprising:
a skill level storage unit which stores worker data in which a worker ID for identifying each of the workers is associated with a skill level of the corresponding worker for execution of each of the jobs;
a history data storage unit which stores execution results of the jobs executed by the workers as job history data for each of the workers; and
a worker data update unit which updates the skill level of each of the workers in the worker data based on a result of determination extracted from the job history data.

2. The component mounting system according to claim 1,
wherein the job history data comprise information indicating a change in failure occurrence state of equipment operation before and after execution of each of the jobs, and
wherein the result of determination is derived from the change in failure occurrence state.

3. A component mounting method in which workers execute jobs for equipment operation of a component mounting line comprising series-connected component mounting machines, said component mounting method comprising:
storing worker data in which a worker ID for identifying each of the workers is associated with a skill level of the corresponding worker for execution of each of the jobs;
storing results of execution of the jobs executed by the workers as job history data for each of the workers; and
updating the skill level of each of the workers in the worker data based on a result of determination extracted from the job history data.

4. The component mounting method according to claim 3,
wherein the job history data comprise information indicating a change in failure occurrence state of equipment operation before and after execution of each of the jobs, and
wherein the result of determination is derived from the change in failure occurrence state.
